(19) United States
(12) Patent Application Publication
(10) Pub. No.: US 2006/0214218 A1
(43) Pub. Date: Sep. 28, 2006

(54) Semiconductor device and method of fabricating the same

(76) Inventors: Kiyokazu Shishido, Aizuwakamatsu-shi (JP); Masahiko Higashi, Aizuwakamatsu-shi (JP); Minh Van Ngo, Fremont, CA (US); Angela T. Hui, Fremont, CA (US); Wenmei Li, Sunnyvale, CA (US); Ning Cheng, San Jose, CA (US); Mark T. Ramsbey, Sunnyvale, CA (US); Hirokazu Tokuno, Cupertino, CA (US); Pei-Yuan Gao, San Jose, CA (US); Takayuki Enda, (US)

Correspondence Address: INGRASSIA FISHER & LORENZ, P.C., 7150 E. CAMELBACK, STE. 325, SCOTTSDALE, AZ, 85251, US

(21) Appl. No.: 11/258,823

(22) Filed: Oct. 25, 2005

Related U.S. Application Data
(63) Continuation of application No. PCT/JP04/15774, filed on Oct. 25, 2004.

(51) Int. Cl. H01L 29/792

(52) U.S. Cl. 257/315; 257/324; 257/E29.304

(57) ABSTRACT

A semiconductor device includes a semiconductor substrate, an ONO film that is provided on the semiconductor substrate and has a contact hole, and an interlayer insulating film that is provided directly on the ONO film and contains phosphorus. The interlayer insulating film contains 4.5 wt % of phosphorus or more in an interface portion that interfaces with the ONO film. The interlayer insulating film comprises a first portion that contacts the ONO film, and a second portion provided on the first portion. The first portion has a phosphorus concentration more than that of the second portion.

### CROSS-REFERENCES TO RELATED APPLICATIONS

This is a continuation of International Application No. PCT/JP2004/015774, filed Oct. 25, 2004 which was not published in English under PCT Article 21(2).

### BACKGROUND OF THE INVENTION

1. Field of the Invention

The present invention relates to semiconductor devices and methods of fabricating the same, and more particularly, to a non-volatile semiconductor memory having an ONO (Oxide/Nitride/Oxide) film and a method of fabricating the same.

2. Description of the Related Art

Recently, programmable non-volatile semiconductor memories have been widely used and there has been considerable activity in the development of an increased number of bits per unit area and reduction of the cost per bit.

Typical examples of non-volatile memories are floating-gate type flash memories of a NOR or NAND array. The floating-gate type flash memories having the NOR array are advantageously random accessible, yet require a bit line contact for each cell. This bit line requirement prevents improvements in the integration density. The floating-gate type flash memories having the NAND array are advantageously capable of realizing a highly integrated array of cells, which are connected in series to reduce the number of bit line contacts, however they are random inaccessible. Further, processing of floating-gate type flash memories have poor controllability of forming a thin tunnel insulation film, which is a technical drawback in increasing the memory capacity.

In order to cope with the above-mentioned problems, there is a known method of locally retaining charge and storing multi-valued data in a single cell. The normal floating-gate type flash memory reads a change of the threshold voltage of the cell transistor by controlling the amount of charge accumulated in the floating gate in spatially even fashion. In contrast, flash memory capable of storing multi-valued data in a single cell has a gate insulation film partially formed by a substance capable of trapping the charge and reads a change of the threshold voltage of the cell transistor by controlling the amount of charge trapped in the substance. More specifically, the gate insulation film located just below the gate electrode has an ON or ONO structure, and the charge is locally accumulated in a Si₃N₄ film close to the source/drain regions of the transistor. With this structure, multiple bits of data can be stored per cell. For this type of memory, a buried bit line type SONOS memory is known. In this type of memory, the buried bit lines function as the source and drain of each cell. Thus, in the following description, the term “bit line” may be used when the source and drain of the cell is referred to.

The buried bit line SONOS memory has a simple structure, as compared to the floating-gate type cell, and has the further features of random access, a non-contact array structure, and the capability of storing two bits per cell (reducing the cell area by approximately ½). Thus, the buried bit line SONOS memory is industrially very useful. The buried bit line structure also has an array in which the source/drain diffused regions, which are the bit lines of the SONOS memory, are formed below the word lines and each transistor in the NOR array does not need the bit line contact window.

In order to reduce the resistance of the bit lines, metal wiring layers are formed on an interlayer insulating film on the ONO film and are connected to the bit lines via contact holes formed in the interlayer insulating film and the ONO film.

An interlayer insulating film having a double layer structure applied to the floating-gate type flash memory is proposed in Japanese Patent No. 2791090. The proposed insulation film is composed of an upper layer and a lower layer. The lower layer is formed on a silicon oxide film that covers the gate electrode and substantially includes no impurity, and has a high phosphorous concentration and a low boron concentration. The upper layer has a lower phosphorous concentration and a higher boron concentration than the lower layer. The above Patent describes the following: The upper BPSG film is not likely to absorb moisture because of the low phosphorous concentration, while the lower layer is likely to absorb moisture because of the high phosphorous concentration, so that the interlayer insulating film is capable of preventing moisture from entering therein from the outside and the moisture entering into the interlayer insulating film is fixed to the lower BPSG film. It is thus possible to prevent moisture from reaching the device surface and prevent all the charge stored in the floating gate made of a conductor from flowing out if the gate oxide film is damaged due to moisture.

However, the flash memory having the ONO film stores the charge in a nitride film made of an insulator unlike the floating type flash memory. It is thus considered that, even when moisture seepage is effectively prevented as described in the Patent, this does not directly improve the data retention. Thus, it is still desired to provide means for improving the data retention of flash memory with an ONO film.

### SUMMARY OF THE INVENTION

It is an object of the present invention to improve charge loss and data retention in flash memory with an ONO film.

According to an aspect of the present invention, there is provided a semiconductor device including: a semiconductor substrate; an ONO film that is provided on the semiconductor substrate and has a contact hole; and an interlayer insulating film that is provided directly on the ONO film and contains phosphorus.

The semiconductor device may further include a gate electrode provided on the ONO film, wherein the interlayer insulating film is provided directly on the gate electrode. The semiconductor device may further include a gate electrode provided on the ONO film, wherein the interlayer insulating film is in contact with a silicide region formed on top of the gate electrode.

Preferably, the interlayer insulating film contains 4.5 per cent by weight (wt %) of phosphorus or more in an interface portion that interfaces with the ONO film. More specifically, the interlayer insulating film contains 4.5 wt % of phosphorus or more but 10.0 wt % or less in an interface portion that interfaces with the ONO film.

For example, the interlayer insulating film includes a first portion that contacts the ONO film, and a second portion provided on the first portion, in which the first portion has a phosphorus concentration more than that of the second portion. The second portion contains boron.

The interlayer insulating film may be a CVD oxide film or an SOD (Spin On Dielectric) film. The CVD oxide film may be a tetraethylorthosilicate (TEOS) oxide film or a high density plasma (HDP) oxide film.

According to another aspect of the present invention, there is provided a method of fabricating a semiconductor device including the steps of: forming an ONO film on a semiconductor substrate in which a diffused region is formed; forming an interlayer insulating film containing phosphorus on the ONO film; and forming a contact hole in the interlayer insulating film and the ONO film and then forming a metal interconnection line on the interlayer insulating film, the metal interconnection line contacting the diffused region via the contact hole. Preferably, the step of forming an interlayer insulating film forms the interlayer insulating film so that it contains 4.5 wt % of phosphorus or more.

It is anticipated that phosphorous included in the interlayer insulating film functions to bring about gettering of mobile ions entering a contact in a contact hole formed in the ONO film and to suppress charge loss and improve the data retention. Particularly, the interlayer insulation film including phosphorous is formed directly on the ONO film, so that the effects of gettering of mobile ions can be effectively brought about.

### BRIEF DESCRIPTION OF THE DRAWINGS

Reference is made to the attached drawings, in which:

FIGS. 1(A) and 1(B) illustrate experimental results, wherein FIG. 1(A) is a graph of the relationship between the conditions for growth of a BPSG film and the boron concentration, and FIG. 1(B) is a graph of the relationship between the conditions for growth of a BPSG film and the phosphorous concentration;

FIG. 2 illustrates the experimental results showing the relationship between the phosphorous concentration of an initial layer of the BPSG film and the defective ratio;

FIG. 3(A) is a cross-sectional view of a semiconductor device according to an embodiment of the present invention;

FIG. 3(B) shows a structure of an ONO film employed in the semiconductor device shown in FIG. 3(A);

FIG. 4 is a graph comparatively showing the effects of the embodiment and those of a comparative example; and

FIGS. 5(A) and 5(B) illustrate a fabrication process of the semiconductor device according to an embodiment of the present invention.

### DESCRIPTION OF THE PREFERRED EMBODIMENTS

The present inventors identified a cause that degrades data retention in flash memory with an ONO film.

In experiments conducted by the inventors, a borophosphosilicate glass (BPSG) film is grown on an ONO film, and the boron concentration and the phosphorous concentration were measured. The experimental results show that the boron concentration after growth is almost constant without depending on the film thickness, while the phosphorous concentration is not even in the thickness direction but, instead, has a slope. Particularly, the phosphorous concentration at an interface (which is defined as an initially grown portion of the BPSG deposited on the ONO film at the initial stage of growth) is extremely low.

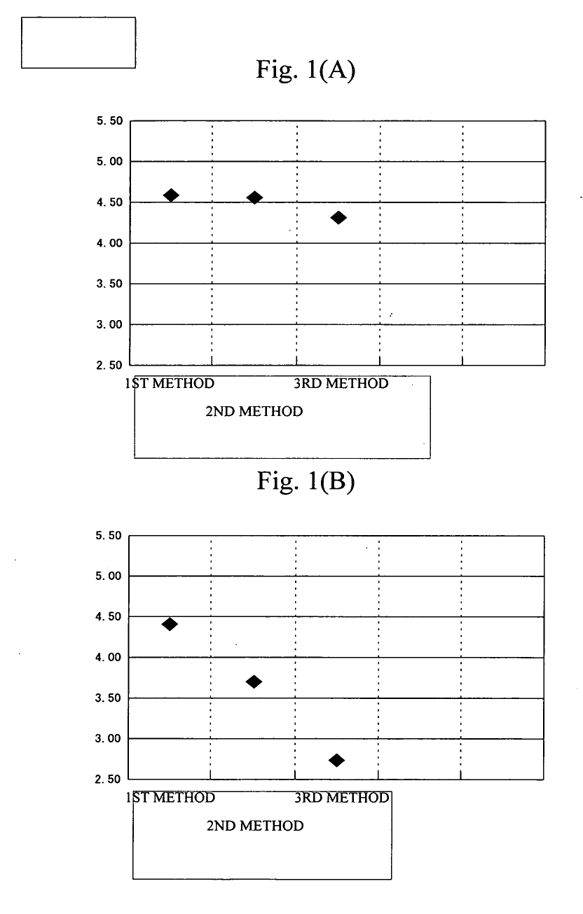

FIGS. 1(A) and 1(B) show the above experimental results, in which the horizontal axes denote three different methods of growing films mentioned below, and the vertical axes denote the phosphorous concentration. In the experiments, BPSG films each having a thickness of 0.6 μm (6000 angstroms) were grown by the following three different processes. The first process grew two BPSG films each having a thickness of 0.3 μm. The second process grew four BPSG films each having a thickness of 0.15 μm. The third process grew six BPSG films each having a thickness of 0.1 μm. The films were grown so that each of the BPSG films after growth has a boron concentration of 4.5 wt % and a phosphorous concentration of 4.5 wt %. FIG. 1(A) shows the boron concentration, and FIG. 1(B) shows the phosphorous concentration. It can be seen that the boron concentration is almost constant regardless of the thickness of the BPSG film, while the phosphorous concentration becomes low as the BPSG film becomes thin. That is, the experimental results shown in FIG. 1(B) show that the initial layer of the BPSG film that is 0.6 μm thick close to the interface with the ONO film has a low concentration.

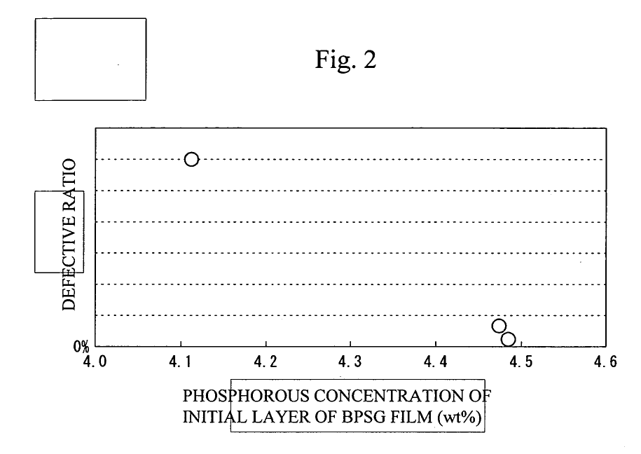

Further, the present inventors investigated, through the experiments, the relationship between the above-mentioned experimental results and the data retention of the flash memory having the ONO film. FIG. 2 is a graph showing the relationship between the phosphorous concentration of the initial layer of the BPSG film and the defective ratio because of charge loss. It can be seen from FIG. 2 that the defective ratio is about 0% when the initial layer has a phosphorous concentration of 4.5 wt %, and is another case where the defective ratio is high when the initial layer has a phosphorous concentration of 4.1 wt %. It is easily anticipated that the defective ratio gradually rises in the range of 4.5 wt % to 4.1 wt %, and it is apparent that the defective ratio is about 0% at a phosphorous concentration over 4.5 wt %. However, crystallization and deposition of impurities is detected when the total concentration of phosphorous and boron in the BPSG film exceeds 10.0 wt %. It is thus preferable that the total impurity concentration in the BPSG film is equal to or less than 10 wt %.

As will be described later, it is considered that phosphorous functions to bring about gettering of mobile ions that enters the contact holes from the ONO film. In this case, the interface portion may be an insulation film that does not include boron but includes phosphorous only. Since boron is not involved in gettering of mobile ions, it is rather preferable that the portion of the interlayer insulating film close to the interface (which portion corresponds to an interface portion, the initial layer or the first portion, as will be described later) does not contain boron. In this case, the portion of the interlayer insulating film close to the interface may have a phosphorous concentration in the range of 4.5 wt % to 10.0 wt %.

Preferably, the interface portion (which is referred to as the first portion of the interlayer insulating film) and the remaining portion (which is referred to as the second portion of the interlayer insulating film) are formed as follows. The first portion is a phosphosilicate glass (PSG) film that includes phosphorous in the range of 4.5 wt % to 10.0 wt %, and the second portion is a BPSG film in which the total of the phosphorous concentration and the boron concentration is equal to or less than 10.0 wt %. The first portion formed by the PSG film contacts the ONO film. In this case, it is not essential that the phosphorous concentration is uniform over the first portion. Phosphorous may be included in the PSG film with a concentration slope in the range of 4.5 wt % to 10.0 wt %. For example, the phosphorous concentration may decrease in relationship to the distance from the interface with the ONO film. In addition, the phosphorous concentration of the first portion may be equal to or greater than that of the second portion. When phosphorous gettering of mobile ions in the vicinity of the interface is considered, it is preferable that the phosphorous concentration of the first portion close to the interface is higher than that of the second portion. The two-layer structure is not essential to achieve the objects of the present invention, and any structure composed of an arbitrary number of layers may be employed as long as the total concentration of impurities ranges from 4.5 wt % to 10.0 wt %.

Preferably, the interface portion that has a phosphorous concentration equal to or greater than 4.5 wt %, i.e., the first portion, has a thickness of at least 0.02 μm. It is anticipated that a thickness equal to or greater than 0.02 μm functions to exclude the influence of gettering of mobile ions and results in good data retention. More specifically, preferably, the thickness of the first portion ranges from 0.02 μm to 0.20 μm. Preferably, the thickness of the interface portion is also selected so that the effects of phosphorous gettering are brought about and no voids occur. The upper limit of the thickness of the interface portion is equal to or less than ½ of the minimum distance between the electrodes buried by the interlayer insulating film.

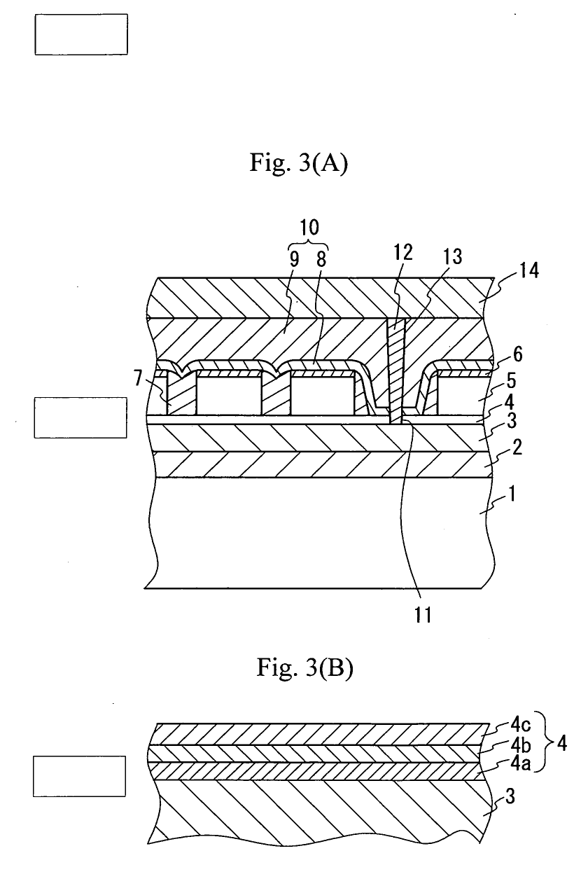

FIG. 3(A) is a cross-sectional view of a semiconductor device according to an embodiment of the present invention, and shows a core section of a flash memory. Referring to this figure, a well region 2 is formed in a surface portion of a semiconductor substrate 1 made of, for example, silicon. And a bit line region 3 is formed in the well region 2. An ONO film 4 is formed on the entire surface of the core section of the semiconductor substrate 1. As shown in FIG. 3(B), the ONO film 4 has an ONO structure composed of a tunnel insulation film 4a, a nitride film 4b for storage, and an oxide film 4c, which films are laminated in this order over the semiconductor substrate 1. The nitride film 4b retains the trapped charge. A contact hole 11 is formed in the ONO film 4. Gate electrodes 5 are formed on the ONO film 4, and sidewalls 7 are formed on the sides of the gate electrodes 5. Silicided CoSi₂ regions 6 are formed on the upper surfaces of the gate electrodes 5. Co in the silicide film may be replaced by Ti, Ni or Pt.

An interlayer insulating film 10 is directly formed on the ONO film 4 in the vicinity of the contact hole 11, the CoSi₂ regions 6 and the sidewalls 7. That is, the interlayer insulating film 10 is in contact with the ONO film and the CoSi₂ regions 6. The interlayer insulating film 10 has the structure that has been described previously. The interlayer insulating film 10 shown in FIG. 3(A) may be a CVD oxide film or an SOD (Spin On Dielectric) film. The CVD oxide film may be a TEOS oxide film or an HDP oxide film. The interlayer insulating film 10 has a two-layer structure composed of a first portion 8 and a second portion 9. The first portion 8 may be a PSG film and the second portion 9 may be a BPSG film. The phosphorous concentration of the PSG film 8 (more specifically, the phosphorous concentration immediately after deposition of the PSG film) ranges from 4.5 wt % to 10.0 wt %, and has a thickness of 0.05 μm. The phosphorous concentration of the BPSG film 9 (more specifically, the phosphorous concentration immediately after deposition of the BPSG film) is, for example 2.9 wt %, and is about 1.15 μm thick just after growth of the film. The BPSG film 9 may have a thickness of 0.8 μm in the finalized device for shipping due to a post-process such as CMP. In this case, the BPSG film 9 has an arbitrary boron concentration equal to or less than 7.1 wt %. If the boron concentration is too low, voids will occur. Taking the above into consideration, an appropriate boron concentration may be selected.

A contact hole 13, which continues to the contact hole 11 formed in the ONO film 4, is formed in the interlayer insulating film 10. A metal wiring layer 14 formed on the interlayer insulating film 10 and the bit line region 3 are electrically connected through the contact holes 11 and 13 (which are full of a conductor 12).

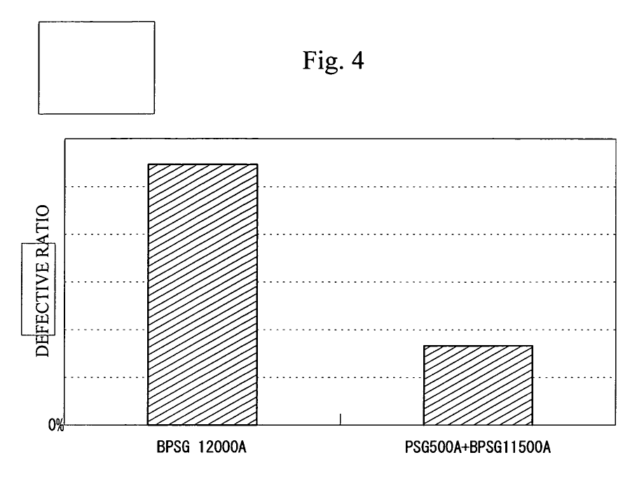

FIG. 4 shows the defective ratio of the devices according to the present embodiment and the defective ratio of comparative devices with the interlayer insulating film 10 made of BPSG (the phosphorous concentration in the interface portion is 2.9 wt %). The interlayer insulating films of the comparative devices are 1.2 μm thick just after growth of the films and are 0.8 μm after CMP, as in the case of the devices according to the present embodiment. It can be seen from FIG. 4 that the devices of the present embodiment have an improved defective ratio, as compared with comparative devices. One of the reasons for this improvement may be phosphorous gettering of mobile ions in which phosphorous in the first portion 8 of the interlayer insulating film 10 brings about gettering of mobile ions entering the conductor 12 in the contact hole 11 from the ONO film 4. It is anticipated that phosphorous gettering is effectively brought about because the first portion 8 is directly in contact with the ONO film 4.

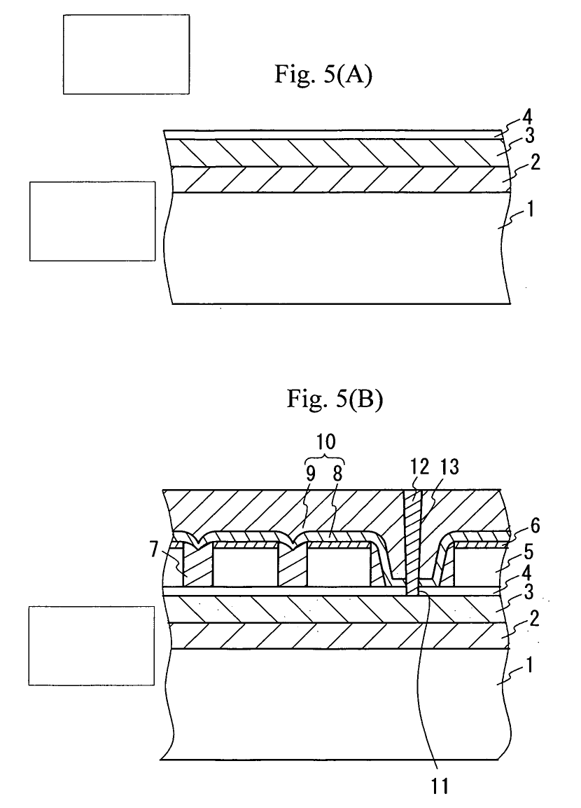

FIGS. 5(A) and 5(B) show a process of fabricating the device according to the present embodiment. More specifically, FIG. 5(A) shows a process until the ONO film 4 is grown on the semiconductor substrate 1. The well region 2 is formed in the semiconductor substrate 1 by a conventional process, and the tunnel insulation film 4a, the nitride film 4b for storage, and the oxide film 4c are sequentially laminated so that the film 4 having the ONO structure can be formed. An opening for forming the bit line region 3 is formed in the laminate in the given position by a photolithography technique. Ions are implanted via the opening so that the bit line region 3 can be formed.

More specifically, the ONO film and the opening are formed as follows. The main surface of the semiconductor substrate 1, from which an insulation film on the core section and a peripheral circuit section (not shown) have been removed by the HF process, is thermally oxidized to form the tunnel oxide to a thickness of 7 nm. Then, the CVD nitride film is deposited on the tunnel oxide film to a thickness of 10 nm, and the CVD oxide film is deposited on the CVD nitride film. Then, ions are implanted through the opening for forming the bit line at 50 KeV and a dose of 1.0×10¹⁵ cm⁻² so that the bit line region 3 is formed. The ONO film 4 is formed in not only the core section but also the peripheral circuit section, which does not need the ONO film 4. Thus, the ONO film 4 in the peripheral circuit section may be removed by a resist patterning technique.

Then, as shown in FIG. 5B, a conductive film for the gate electrodes is grown on the ONO film, and is shaped into the gate electrodes 5 (word lines) by resist patterning and etching. The conductive film for the gate electrodes 5 may be a polysilicon film that is formed by CVD and is 0.18 μm thick. Then, the sidewalls 7 are formed on the sides of the gate electrodes 5. Subsequently, the CoSi₂ regions 6 are formed by the silicide process with cobalt.

Then, a silicon oxide film is deposited by CVD such as TEOS or HDP to form the interlayer insulating film 10. During the deposition process, the dose of phosphorous and the dose of boron are controlled so as to obtain the interlayer insulating film 10 having the aforementioned structure. Thereafter, the contact hole 13 is formed in the interlayer insulating film 10, and the contact hole 11 is formed in the ONO film 4. Then, the contact holes 11 and 13 are filled with the conductor 12, and the metal wiring layer 14 is formed.

Some embodiments and examples of the present invention have been described. The present invention is not limited to the specifically described embodiments and examples, but includes various embodiments and examples within the scope of the invention. The present invention includes not only semiconductor memory devices such as flash memories but also semiconductor devices equipped with flash memories and other semiconductor circuits.

1. A semiconductor device comprising:
a semiconductor substrate;
an ONO film that is provided on the semiconductor substrate and has a contact hole; and
an interlayer insulating film that is provided on the ONO film and includes first and second portions;
wherein the first portion comprises a PSG film that is provided directly on the ONO film and has a phosphorus concentration in the range of 4.5 wt % to 10.0 wt %; and
wherein the second portion comprises a BPSG film that is provided on the first portion and has a total of a phosphorus concentration and a boron concentration equal to or less than 10.0 wt %.

2. The semiconductor device as claimed in claim 1, further comprising a gate electrode provided on the ONO film, wherein the interlayer insulating film is provided directly on the gate electrode.

3. The semiconductor device as claimed in claim 1, further comprising a gate electrode provided on the ONO film, wherein the interlayer insulating film is in contact with a silicide region formed on top of the gate electrode.

4. (canceled)

5. (canceled)

6. The semiconductor device as claimed in claim 1, wherein the first portion has a phosphorus concentration more than that of the second portion.

7. (canceled)

8. The semiconductor device as claimed in claim 1 wherein the interlayer insulating film is an oxide film.

9. The semiconductor device as claimed in claim 1 wherein the interlayer insulating film is one of a CVD oxide film and a SOD (Spin On Dielectric) film.

10. The semiconductor device as claimed in claim 1 wherein the interlayer insulating film is one of a TEOS oxide film and a HDP oxide film.

11. A method of fabricating a semiconductor device comprising the steps of:
forming an ONO film on a semiconductor substrate in which a diffused region is formed;
forming an interlayer insulating film containing phosphorus on the ONO film;
forming a contact hole in the interlayer insulating film and the ONO film; and
forming a metal interconnection line on the interlayer insulating film, the metal interconnection line contacting the diffused region via the contact hole, wherein the step of forming the interlayer insulating film includes the steps of:
forming a first portion of the interlayer insulating film comprising a PSG film provided directly on the ONO film and containing phosphorus in the range of 4.5 wt % to 10.0 wt %; and
forming a second portion of the interlayer insulating film comprising a BPSG film provided on the first portion and containing a total of a phosphorus concentration and a boron concentration equal to or less than 10.0 wt %.

12. (canceled)
